(19) United States
(12) Patent Application Publication
(10) Pub. No.: US 2026/0038555 A1
(43) Pub. Date: Feb. 5, 2026

(54) VOLTAGE DRIVERS WITH CONFIGURABLE PULL-UP AND PULL-DOWN AMPLIFIERS

(71) Applicant: Micron Technology, Inc., Boise, ID (US)

(72) Inventors: Subhasis Sasmal, Hyderabad (IN); Masudur Rahaman Molla, Hyderabad (IN)

(21) Appl. No.: 19/275,751

(22) Filed: Jul. 21, 2025

Related U.S. Application Data
(60) Provisional application No. 63/677,543, filed on Jul. 31, 2024.

(51) Int. Cl. G11C 11/22; H03F 3/45; H03K 17/687

(52) U.S. Cl. CPC G11C 11/2297; H03F 3/45475; H03K 17/687

(57) ABSTRACT

Methods, systems, and devices for voltage drivers with configurable pull-up and pull-down amplifiers are described. For example, a driver may be configured with a pull-up (e.g., sourcing) amplifier and a pull-down (e.g., sinking) amplifier in a unity gain configuration, with outputs of such amplifiers being tied in an electrically parallel arrangement. The pull-down amplifier may be tied to a relatively low voltage to support a lower end of a sinking voltage regulation range, and the pull-up amplifier may be tied with a relatively higher voltage to support a lower end of a sourcing voltage regulation range that is higher than the lower end of the sinking voltage regulation range. Such an arrangement may implement various techniques to enable one of the pull-down amplifier or the pull-up amplifier, which also may disable the other of the pull-down amplifier or the pull-up amplifier.

### CROSS REFERENCE

The present Application for Patent claims priority to U.S. Patent Application No. 63/677,543 by Sasmal et al., entitled “VOLTAGE DRIVERS WITH CONFIGURABLE PULL-UP AND PULL-DOWN AMPLIFIERS,” filed Jul. 31, 2024, which is assigned to the assignee hereof, and which is expressly incorporated by reference in its entirety herein.

### TECHNICAL FIELD

The following relates to one or more systems for electronic devices, including voltage drivers with configurable pull-up and pull-down amplifiers.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a memory device that supports voltage drivers with configurable pull-up and pull-down amplifiers in accordance with examples as disclosed herein.

FIGS. 2 and 3 show examples of circuits that support voltage drivers with configurable pull-up and pull-down amplifiers in accordance with examples as disclosed herein.

FIGS. 4A and 4B shows examples of implementing voltage drivers with configurable pull-up and pull-down amplifiers in accordance with examples as disclosed herein.

FIG. 5 shows an example of a circuit that supports voltage drivers with configurable pull-up and pull-down amplifiers in accordance with examples as disclosed herein.

FIG. 6 shows an example of a flowchart that supports voltage drivers with configurable pull-up and pull-down amplifiers in accordance with examples as disclosed herein.

### DETAILED DESCRIPTION

Some electronic devices may implement one or more drivers (e.g., voltage drivers, output drivers, amplifiers, bleeder amplifiers) that support current, via a driver output, in accordance with a voltage that is regulated by the driver(s). For example, memory devices may implement drivers that support operations of sense amplifiers (e.g., for detecting logic states of memory cells), or evaluations thereof (e.g., for performing sense amplifier margin evaluations), that are based on a regulated voltage. Some operations of an electronic device, such as operations involving sense amplifiers in a memory device, may rely on drivers that support both a current sourcing capability (e.g., supporting a current output from drivers, such as a forward current, in accordance with a regulated voltage) and a current sinking capability (e.g., supporting a current input to drivers, such as a reverse current, in accordance with a regulated voltage). In some such implementations, a current sourcing capability may be associated with a first range of voltage regulation (e.g., voltages above a middle voltage of an overall range of voltage regulation) and a current sinking capability may be associated with a second range of voltage regulation (e.g., voltages below the middle voltage of the overall range of voltage regulation. However, some techniques for implementing such driver capabilities, such as conventional class-AB amplifier techniques, may be associated with limitations for providing suitable voltage ranges for sourcing or sinking capabilities, or reliability concerns, among other drawbacks.

In accordance with examples as described herein, a driver (e.g., a driver circuit, a voltage driver circuit, a voltage regulation circuit, an amplifier circuit, an amplifier structure) may be configured to support a relatively wide operational range (e.g., a relatively wide range of voltage regulation) and a relatively large range of current sourcing and sinking (e.g., positive and negative current, up to +/−2 milliamps). For example, such a driver may be configured with a pull-up (e.g., sourcing) amplifier and a pull-down (e.g., sinking) amplifier in a unity gain configuration, with outputs of such amplifiers being tied in an electrically parallel arrangement. The pull-down amplifier may be tied to a relatively low voltage (e.g., a negative voltage, a negative supply) to support a lower end of a sinking voltage regulation range (e.g., to support regulation down to a ground voltage, such as 0V). The pull-up amplifier may be tied with a relatively higher voltage (e.g., a ground voltage, a ground supply) to support a lower end of a sourcing voltage regulation range (e.g., to support regulation down to a middle voltage of the overall regulation range) that is higher than the lower end of the sinking voltage regulation range. Such an arrangement may implement various techniques to enable one of the pull-down amplifier or the pull-up amplifier (e.g., based on a target voltage for regulation), such as control logic that is based on values of a register (e.g., a shift register) or a fuse array, which also may disable the other of the pull-down amplifier or the pull-up amplifier (e.g., to avoid redundant or counteractive operations between the pull-up and pull-down amplifiers). In some examples, such values of the register or fuse array may also be used to set a voltage of the regulation (e.g., using logic circuitry, using a multiplexing circuitry associated with a resistance ladder, in addition to enabling or disabling pull-up or pull-down circuitry), such as a reference voltage of a reference generator. Implementing such techniques may improve reliability and reduce voltage regulation offsets compared with other techniques (e.g., based on discrete operations of either the pull-up or pull-down amplifiers, avoiding bidirectional current driving), and also may involve smaller components (e.g., smaller transistors, transistors with a smaller area, a smaller area of a semiconductor component) than other architectures, such as conventional class-AB amplifiers.

In addition to applicability in memory systems as described herein, techniques for voltage drivers including configurable pull-up and pull-down amplifiers may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing capabilities of electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving resolution and responsiveness for voltage regulation to support a given current demand, which may improve processing reliability, decrease processing or latency times, improve response times, or otherwise improve user experience, among other benefits.

Features of the disclosure are illustrated and described in the context of electronic devices such as memory devices. Features of the disclosure are further illustrated and described in the context of circuits, circuit implementations, and flowcharts.

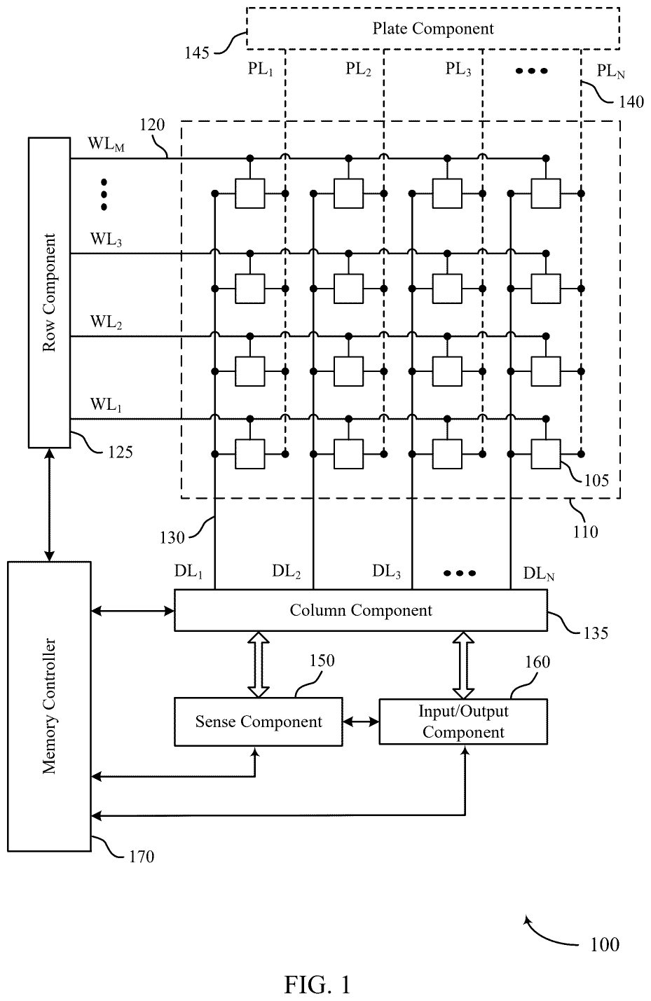

FIG. 1 shows an example of a memory device 100 that supports voltage drivers with configurable pull-up and pull-down amplifiers in accordance with examples as disclosed herein. The memory device 100 may be referred to as a memory die or an electronic memory apparatus. Aspects of a memory device 100 may be implemented in a semiconductor component, such as one or more semiconductor dies.

The memory device 100 includes memory cells 105 that are programmable to store information. In some examples, a memory cell 105 may be operable to store one bit of information at a time (e.g., a logic 0 or a logic 1). In some examples, a memory cell 105 (e.g., a multi-level memory cell) may be operable to store more than one bit of information at a time (e.g., a logic 00, logic 01, logic 10, a logic 11). Memory cells 105 may be arranged in an array, such as in a memory array 110, which may refer to a contiguous set of memory cells 105 (e.g., a contiguous set of elements of a semiconductor chip).

In some examples, a memory cell 105 may store an electric charge representative of the programmable logic states in a storage component (e.g., a capacitor, a capacitive memory element, a capacitive storage element). In some examples, a charged and uncharged capacitor may represent two logic states, respectively. In some other examples, a positively charged (e.g., a first polarity, a positive polarity) and negatively charged (e.g., a second polarity, a negative polarity) capacitor may represent two logic states, respectively. DRAM or FeRAM architectures may use such designs, and the capacitor employed may include a dielectric material with linear or para-electric polarization properties as an insulator. In some examples, different levels of charge of a capacitor may represent different logic states, which, in some examples, may support more than two logic states in a respective memory cell 105. In some examples, such as FeRAM architectures, a memory cell 105 may include a ferroelectric capacitor having a ferroelectric material as an insulating (e.g., non-conductive) layer between terminals of the capacitor. Different levels or polarities of polarization of a ferroelectric capacitor may represent different logic states (e.g., supporting two or more logic states in a respective memory cell 105).

In some examples, a memory cell 105 may include or otherwise be associated with a configurable material, which may be referred to as a material memory element, a material storage element, a material portion, and other nomenclature. The configurable material may have one or more variable and configurable characteristics or properties (e.g., material states) that may represent different logic states. For example, a configurable material may take different forms, different atomic configurations, different degrees of crystallinity, different atomic distributions, or otherwise maintain different characteristics that may be leveraged to represent one logic state or another. In some examples, such characteristics may be associated with different electrical resistances, different threshold characteristics, or other properties that are detectable or distinguishable during a read operation to identify a logic state written to or stored by the configurable material.

In some cases, a configurable material of a memory cell 105 may be associated with a threshold voltage. For example, electrical current may flow through the configurable material when a voltage greater than the threshold voltage is applied across the memory cell 105, and electrical current may not flow through the configurable material, or may flow through the configurable material at a rate below some level (e.g., according to a leakage rate), when a voltage less than the threshold voltage is applied across the memory cell 105. Thus, a voltage applied to memory cells 105 may result in different current flow, or different perceived resistance, or a change in resistance (e.g., a thresholding or switching event) depending on whether a configurable material portion of the memory cell 105 was written with one logic state or another. Accordingly, the magnitude of current, or other characteristic (e.g., thresholding behavior, resistance breakdown behavior, snapback behavior) associated with the current that results from applying a read voltage to the memory cell 105, may be used to determine a logic state written to or stored by memory cell 105.

In the example of memory device 100, each row of memory cells 105 may be coupled with one or more word lines 120 (e.g., WL₁ through WL_{M}), and each column of memory cells 105 may be coupled with one or more digit lines 130 (e.g., DL₁ through DL_{N}). Each of the word lines 120 and digit lines 130 may be an example of an access line of the memory device 100. In general, one memory cell 105 may be located at the intersection of (e.g., coupled with, coupled between) a word line 120 and a digit line 130. This intersection may be referred to as an address of a memory cell 105. A target (e.g., selected) memory cell 105 may be a memory cell 105 located at the intersection of an activated or otherwise selected word line 120 and an activated or otherwise selected digit line 130.

In some architectures, a storage component of a memory cell 105 may be electrically isolated from a digit line 130 by a cell selection component, which, in some examples, may be referred to as a switching component or a selector device of or otherwise associated with the memory cell 105. A word line 120 may be coupled with the cell selection component (e.g., via a control node of the cell selection component), and may control the cell selection component of the memory cell 105. For example, the cell selection component may be a transistor and the word line 120 may be coupled with or be a portion of a gate of the transistor (e.g., where a gate node of the transistor may be a control node of the transistor). Activating a word line 120 may result in an electrical connection (e.g., a closed circuit) between a respective storage component of one or more memory cells 105 and one or more corresponding digit lines 130, which may be referred to as activating the one or more memory cells 105 or coupling the one or more memory cells 105 with a respective one or more digit lines 130. A digit line 130 may then be accessed to write to or read from the respective memory cell 105.

In some examples, memory cells 105 may also be coupled with one or more plate lines 140 (e.g., PL₁ through PL_{N}). In some examples, each of the plate lines 140 may be independently addressable (e.g., supporting individual selection or biasing). In some examples, the plurality of plate lines 140 may represent or be otherwise functionally equivalent with a common plate, or other common node (e.g., a plate node common to each of the memory cells 105 of the array 110). For implementations in which a memory cell 105 employs a capacitor for storing a logic state, a digit line 130 may provide access to a first terminal (e.g., a first plate) of the capacitor, and a plate line 140 may provide access to a second terminal (e.g., a second plate) of the capacitor. Although the plurality of plate lines 140 of the memory device 100 are shown as being parallel with the plurality of digit lines 130, in other examples, a plurality of plate lines 140 may be parallel with the plurality of word lines 120, or in any other configuration (e.g., a common planar conductor, a common plate layer, a common plate node).

Access operations such as reading, writing, rewriting, and refreshing may be performed on a memory cell 105 by activating (e.g., selecting, applying a voltage to) a word line 120, a digit line 130, or a plate line 140 coupled with the memory cell 105, which may include applying a voltage, a charge, or a current to the respective access line. After selecting a memory cell 105 (e.g., in a read operation), a resulting signal may be used to determine the logic state stored by the memory cell 105. For example, a memory cell 105 with a capacitive memory element storing a logic state may be selected, and the resulting flow of charge via an access line or resulting voltage of an access line may be detected to determine the programmed logic state stored by the memory cell 105.

Accessing memory cells 105 may be controlled using a row component 125 (e.g., a row decoder), a column component 135 (e.g., a column decoder), or a plate component 145 (e.g., a plate decoder), or a combination thereof. For example, a row component 125 may receive a row address from the memory controller 170 and activate a corresponding word line 120 based on the received row address. Similarly, a column component 135 may receive a column address from the memory controller 170 and activate a corresponding digit line 130. In some examples, such access operations may be accompanied by a plate component 145 biasing one or more of the plate lines 140 (e.g., biasing one of the plate lines 140, biasing some or all of the plate lines 140, biasing a common plate).

In some examples, the memory controller 170 may control operations (e.g., read operations, write operations, rewrite operations, refresh operations) of memory cells 105 using one or more components (e.g., row component 125, column component 135, plate component 145, sense component 150). In some cases, one or more of the row component 125, the column component 135, the plate component 145, and the sense component 150 may be co-located with or otherwise included as part of the memory controller 170. The memory controller 170 may generate row and column address signals to activate a desired word line 120 and digit line 130. The memory controller 170 may also generate or control various voltages or currents used during the operation of memory device 100.

A memory cell 105 may be written (e.g., programmed, set) by activating the relevant word line 120, digit line 130, or plate line 140 (e.g., via a memory controller 170). In other words, a logic state may be stored in a memory cell 105. A row component 125, column component 135, or plate component 145 may accept data, for example, via input/output component 160, to be written to the memory cells 105. In some examples, a write operation may be performed at least in part by a sense component 150, or a write operation may be configured to bypass a sense component 150.

In the case of a capacitive memory element, a memory cell 105 may be written by applying a voltage to (e.g., across) a capacitor, and then isolating the capacitor (e.g., isolating the capacitor from a voltage source used to write the memory cell 105, floating the capacitor) to store a charge in the capacitor associated with a desired logic state. In the case of ferroelectric memory, a ferroelectric memory element (e.g., a ferroelectric capacitor) of a memory cell 105 may be written by applying a voltage with a magnitude high enough to polarize the ferroelectric memory element (e.g., applying a saturation voltage) with a polarization associated with a desired logic state, and the ferroelectric memory element may be isolated (e.g., floating), or a zero net voltage may be applied across the ferroelectric memory element (e.g., grounding, virtually grounding, or equalizing a voltage across the ferroelectric memory element). In the case of a material memory architecture, a memory cell 105 may be written by applying a current, voltage, or other heating or biasing to a material memory element to configure the material according to a corresponding logic state.

A memory cell 105 may be read (e.g., sensed) by a sense component 150 when the memory cell 105 is accessed (e.g., in cooperation with the memory controller 170) to determine a logic state written to or stored by the memory cell 105. For example, the sense component 150 may be configured to evaluate a current or charge transfer through or from the memory cell 105, or a voltage resulting from coupling the memory cell 105 with the sense component 150, responsive to a read operation. The sense component 150 may provide an output signal indicative of the logic state read from the memory cell 105 to one or more components (e.g., to the column component 135, the input/output component 160, to the memory controller 170).

A sense component 150 may include various circuitry (e.g., switching components, selection components, transistors, amplifiers, capacitors, resistors, voltage sources) configured to detect or amplify a difference in sensing signals (e.g., a difference between a read voltage and a reference voltage, a difference between a read current and a reference current, a difference between a read charge and a reference charge), which, in some examples, may be referred to as latching. In some examples, a sense component 150 may include a collection of circuit elements that are repeated for each of a set or subset of digit lines 130 coupled with the sense component 150. For example, a sense component 150 may include a separate sensing circuit (e.g., a separate or duplicated sense amplifier, a separate or duplicated signal development component) for each of a set of digit lines 130 coupled with the sense component 150, such that a logic state may be separately detected for a respective memory cell 105 coupled with a respective one of the set of digit lines 130.

Some electronic devices, such as a memory device 100, may implement one or more drivers (e.g., voltage drivers, output drivers, amplifiers, bleeder amplifiers) that support current, via a driver output, in accordance with a voltage that is regulated by the driver. For example, a memory device 100 may implement drivers that support operations of a sense component 150 (e.g., sense amplifiers, for detecting logic states of memory cells), or evaluations thereof (e.g., for performing sense amplifier margin evaluations, which may involve driver circuitry of or coupled with a memory controller 170, a sense component 150, or an input/output component 160, among other circuitry of a memory device 100), that are based on a regulated voltage. Some operations of an electronic device, such as operations involving sense amplifiers in sense component 150, may rely on drivers that support both a current sourcing capability (e.g., supporting a current output from drivers, such as a forward current, in accordance with a regulated voltage) and a current sinking capability (e.g., supporting a current input to drivers, such as a reverse current, in accordance with a regulated voltage). In some such implementations, a current sourcing capability may be associated with a first range of voltage regulation (e.g., voltages above a middle voltage of an overall range of voltage regulation) and a current sinking capability may be associated with a second range of voltage regulation (e.g., voltages below the middle voltage of the overall range of voltage regulation. However, some techniques for implementing such driver capabilities, such as conventional class-AB amplifier techniques, may be associated with limitations for providing suitable voltage ranges for sourcing or sinking capabilities, or reliability concerns, among other drawbacks.

In accordance with examples as described herein, a driver (e.g., a driver circuit, a voltage driver circuit, a voltage regulation circuit, an amplifier circuit, an amplifier structure) may be configured to support a relatively wide operational range (e.g., a relatively wide range of voltage regulation) and a relatively large range of current sourcing and sinking (e.g., positive and negative current). For example, such a driver may be configured with a pull-up (e.g., sourcing) amplifier and a pull-down (e.g., sinking) amplifier in a unity gain configuration, with outputs of such amplifiers being tied in an electrically parallel arrangement. The pull-down amplifier may be tied to a relatively low voltage (e.g., a negative voltage, a negative voltage supply) to support a lower end of a sinking voltage regulation range (e.g., to support regulation down to a ground voltage, such as 0V). The pull-up amplifier may be tied with a relatively higher voltage (e.g., a ground voltage, a ground supply) to support a lower end of a sourcing voltage regulation range (e.g., to support regulation down to a middle voltage of the overall regulation range) that is higher than the lower end of the sinking voltage regulation range. Such an arrangement may implement various techniques to enable one of the pull-down amplifier or the pull-up amplifier (e.g., based on a target voltage for regulation), such as control logic that is based on values of a register (e.g., a shift register) or a fuse array, which also may disable the other of the pull-down amplifier or the pull-up amplifier (e.g., to avoid redundant or counteractive operations between the pull-up and pull-down amplifiers). In some examples, such values of the register or fuse array may also be used to set a voltage of the regulation (e.g., using logic circuitry, using a multiplexing circuitry associated with a resistance ladder, in addition to enabling or disabling pull-up or pull-down circuitry), such as a reference voltage of a reference generator. Implementing such techniques may improve reliability and reduce voltage regulation offsets compared with other techniques (e.g., based on discrete operations of either the pull-up or pull-down amplifiers, avoiding bidirectional current driving), and also may involve fewer components (e.g., fewer transistors, a smaller area of a semiconductor component) than other architectures, such as conventional class-AB amplifiers.

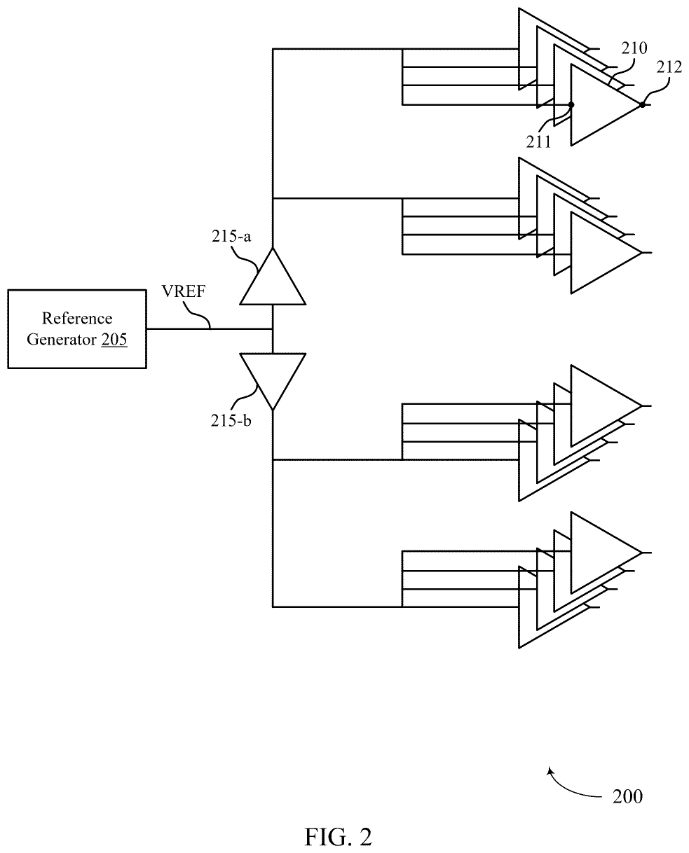

FIG. 2 shows an example of a circuit 200 that supports voltage drivers with configurable pull-up and pull-down amplifiers in accordance with examples as disclosed herein. The circuit 200 may be implemented by an electronic device, such as a memory device 100 (e.g., included in or supporting operations of a sense component 150). The circuit 200 may include a reference voltage generator 205 coupled with one or more voltage driver circuits 210 (e.g., amplifiers, bleeder amplifiers) via buffers 215, which may support distributing driver circuitry across an area of an electronic device (e.g., across different portions of a semiconductor die, to different divisions of circuitry of an electronic device). For example, a circuit 200 may be implemented to provide a voltage driver circuit 210 for each of the banks of a memory device 100 (e.g., each of sixteen banks, associated with one or more arrays 110). Although the circuit 200 illustrates an example with two buffers 215 and sixteen voltage driver circuits 210, various quantities of and configurations of the components of the circuit 200 may be implemented in a memory device 100 or other electronic device in accordance with the described techniques.

Each of the voltage driver circuits 210 may be configured to support a current via a respective output 212 in accordance with a regulated voltage. In some implementations, the voltage driver circuits 210 may be implemented with a unity gain configuration, in which the voltage at the respective output 212 is regulated to be at or near the voltage at a respective input 211 of the voltage driver circuit. In some examples, buffers 215 may also be implemented with a unity gain configuration (e.g., as unity gain buffers), such that the voltage at the respective outputs 212 may each be regulated to be at or near the voltage (e.g., reference voltage, VREF) output by the reference generator 205. Buffers 215 may be implemented to improve transient settling performance of the circuit 200 and may, in some examples, include one or more features similar to the voltage driver circuits 210 (e.g., may include the same or similar circuitry, but with smaller circuit elements to support a smaller current range). In some other examples, buffers 215 may be omitted.

The voltage driver circuits 210 may be implemented to support relatively low-latency voltage regulation in accordance with a relatively low voltage offset (e.g., voltage regulation offset, voltage regulation error) across a relatively wide range of current (e.g., positive and negative current, output and input current, sourcing and sinking current, such as a range of +/−2 milliamps). To support such regulation, each of the voltage driver circuits 210 may be configured with a pull-up amplifier and a pull-down amplifier (e.g., to support a pull-up mode or a pull-down mode, to support current sourcing or sinking). An electronic device that includes the circuit 200 may determine an output voltage of the voltage driver circuits 210 to be regulated (e.g., at the respective outputs 212), and may configure the voltage driver circuits 210 to regulate to the determined output voltage based on configuring the reference generator 205 to output a value of VREF that is equal to the determined output voltage. For example, a reference generator 205 may include a resistor ladder (e.g., between voltage sources having different voltage levels) and logic (e.g., multiplexing logic) to generate a determined value of VREF (e.g., in accordance with values of a register, or one or more fuses, or a combination thereof). In some such examples, a first range (e.g., an upper range, an upper half, a pull-up range) of VREF may be dynamically configurable by way of register values, whereas a second range (e.g., a lower range, a lower half, a pull-down range) may be fixed in a manufacturing operation by way of fuses. Additionally, or alternatively, a first range (e.g., an upper range, an upper half, a pull-up range) of VREF may be configurable with a relatively coarser granularity (e.g., fewer steps, larger steps, in accordance with fewer logic values), whereas a second range (e.g., a lower range, a lower half, a pull-down range) may be configurable with a relatively finer granularity (e.g., more steps, smaller steps, in accordance with more logic values.

Based on the determined output voltage, the electronic device may also be configured to determine whether to enable (e.g., activate) the respective pull-up amplifiers or pull-down amplifiers of each of the voltage driver circuits 210, which may be accompanied by disabling the other of the respective pull-up amplifiers or pull-down amplifiers. In some examples, such techniques may leverage at least some of the same values of a register, or one or more fuses, or combination thereof that are used to determine a value of VREF, which also be used to generate one or more enable or disable values (e.g., binary values, on/off values, in addition to determining a reference voltage from a range of reference voltages). By disabling inactive amplifiers at each of the voltage driver circuits 210 (e.g., preventing both a pull-up mode and a pull-down mode being enabled simultaneously, preventing both a pull-up current path and a pull-down current path from being active simultaneously), the electronic device may improve reliability and reduce voltage regulation offsets compared with other techniques (e.g., based on discrete operations of either the pull-up or pull-down amplifiers, avoiding bidirectional current driving), and also may involve smaller components (e.g., smaller transistors, transistors with a smaller area, a smaller area of a semiconductor component) than other architectures, such as conventional class-AB amplifiers.

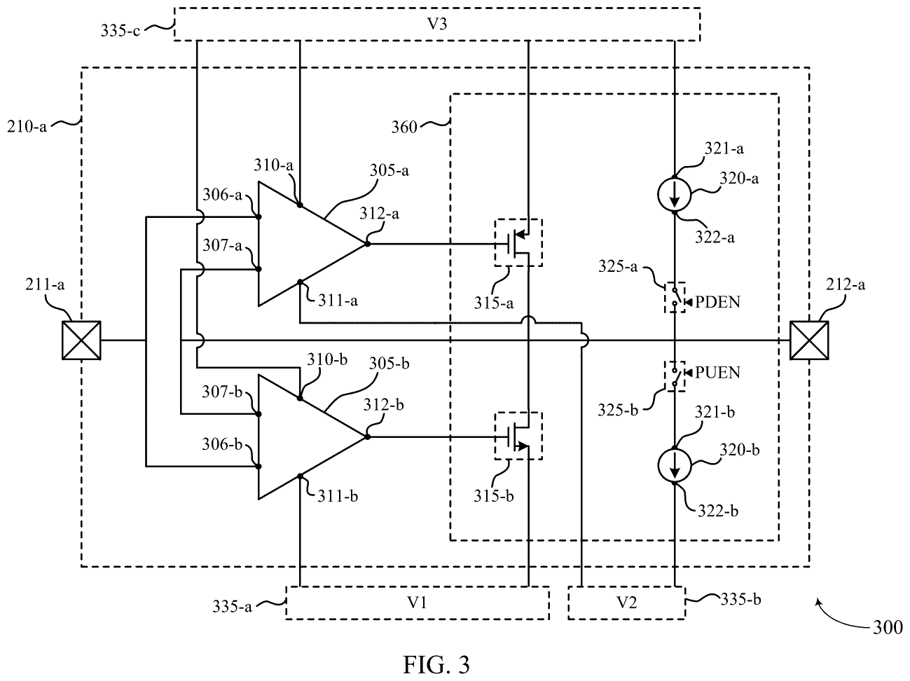

FIG. 3 shows an example of a circuit 300 that supports voltage drivers with configurable pull-up and pull-down amplifiers in accordance with examples as disclosed herein. The circuit 300 may be implemented by an electronic device, such as a memory device 100 (e.g., included in or supporting operations of a sense component 150). The circuit 300 includes a voltage driver circuit 210-a having an input 211-a (e.g., an input node) and an output 212-a (e.g., an output node). The voltage driver circuit 210 may be associated with a unity gain (e.g., between the input 211-a and the output 212-a), in which a voltage at the output 212-a (e.g., a bleeder output voltage, VBLD) is regulated to be at or near a voltage of the input 211-a, which may be coupled with a reference voltage (e.g., a bleeder reference voltage, VREF, a voltage output by a reference generator 205).

The circuit 300 includes voltage sources 335, which may be coupled with one or more voltage supplies of an electronic device that includes the circuit 300. A voltage source 335 may be coupled with a respective voltage supply that is regulated or generated at the electronic device, or is not regulated or generated at the electronic device (e.g., is regulated or otherwise supplied by another device that is coupled with electronic device, and provided by a pin or other input to the electronic device). The voltage source 335-a may be associated with (e.g., may provide, may be configured to output) a voltage V1, which may be a negative supply voltage (e.g., VBB, −0.5V). The voltage source 335-c may be associated with a voltage V3, which may be a positive supply voltage (e.g., VPERI, 1.1V). The voltage source 335-b may be associated with a voltage V2 that is between V1 and V3 (e.g., VSS, 0.0V, a ground voltage, a ground node). Although each of the voltage sources 335 are shown with a direct coupling to components of the voltage driver circuit 210-a, in some examples, one or more of such coupling paths may include one or more switching components operable to couple or isolate the components with the respective voltage source 335, among other components (e.g., buffers, filters, capacitors).

The circuit 300 (e.g., the voltage driver circuit 210-a) also includes transistors 315, each of which may include a respective channel (e.g., a channel portion, a semiconductor channel, a doped semiconductor junction) operable to form a conductive coupling between components, and a respective gate (e.g., a gate portion, a gate node, a control node) operable to modulate a conductivity of the respective channel. For example, the voltage driver circuit 210-a may include a transistor 315-a having a channel operable to couple between the voltage source 335-c and the output 212-a, and a transistor 315-b having a channel operable to couple between the output 212-a and the voltage source 335-a. In some implementations, the transistor 315-a may be a p-type transistor, and the transistor 315-b may be an n-type transistor.

The circuit 300 (e.g., the voltage driver circuit 210-a) also includes switches 325 (e.g., switching components), which may be coupled with or between various components to provide a selective coupling, decoupling, connection, disconnection, or isolation functionality. For example, the voltage driver circuit 210-a may include a switch 325-a operable based on a logical signal PDEN (e.g., a pull-down enable signal), and a switch 325-b operable based on a logical signal PUEN (e.g., a pull-up enable signal). In some examples, one or more of the switches 325 may be implemented as a transistor (e.g., an n-type transistor, a p-type transistor), and a logical signal may be applied to a gate of the transistor to selectively enable or disable a conductive path (e.g., channel) through the transistor. Logical signals may be provided by one or more controllers or other processing circuitry (not shown), such as a memory controller 170 (e.g., in a memory device implementation), or any other component of an electronic device that supports enabling or disabling (e.g., closing, opening) switches 325.

The circuit 300 (e.g., the voltage driver circuit 210-a) also includes current sources 320 (e.g., current generators, bias current sources), each of which may be operable to drive a respective current along a direction from a respective input 321 to a respective output 322 (e.g., based at least in part on a voltage of one or more voltage sources 335). In some examples, such a current may be relatively small, such as I microamp. For example, the voltage driver circuit 210-a may include a current source 320-a operable to drive a current (e.g., via switch 325-a, while closed) to the output 212-a, and a current source 320-b operable to drive a current (e.g., via switch 325-b, while closed) from the output 212-a. In some examples, the input 321-a of the current source 320-a may be operable to couple with the voltage source 335-c and the output 322-a of the current source 320-a may be operable to couple with the output 212-a. In some examples, the input 321-b of the current source 320-b may be operable to couple with the output 212-a and the output 322-b of the current source 320-b may be operable to couple with the voltage source 335-b. In some implementations, the switch 325-a may be coupled between the output 322-a and the output 212-a, and the switch 325-b may be coupled between the output 212-a and the input 321-b.

The circuit 300 (e.g., the voltage driver circuit 210-a) also includes differential amplifiers 305, each of which may be operable to drive (e.g., drive a voltage of, drive a charge via) a respective output 312 based at least in part on voltages at (e.g., a differential voltage between) a respective first differential input 306 and a respective second differential input 307. For example, the voltage driver circuit 210-a may include a differential amplifier 305-a (e.g., a pull-up amplifier) having a first differential input 306-a coupled with the input 211-a (e.g., coupled with a reference voltage, coupled with a reference generator 205) and a second differential input 307-a coupled with the output 212-a (e.g., coupled with an output voltage). The voltage driver circuit 210-a may also include a differential amplifier 305-b (e.g., a pull-down amplifier) having a first differential input 306-b coupled with the input 211-a and a second differential input 307-b coupled with the output 212-a.

Each of the differential amplifiers 305 may be operable based on a first voltage (e.g., a first supply voltage, a relatively positive voltage) provided to a respective first supply input 310 and a second voltage (e.g., a second supply voltage, a relatively negative voltage) provided to a respective second supply input 311. For example, the differential amplifier 305-a may have a first supply input 310-a operable to couple with the voltage source 335-c and a second supply input operable to couple with the voltage source 335-b (e.g., a ground supply voltage). The differential amplifier 305-b may have a first supply input 310-b operable to couple with the voltage source 335-c and a second supply input operable to couple with the voltage source 335-a (e.g., having a lower supply voltage than the input 311-a of the differential amplifier 305-a, such as a negative supply voltage).

The outputs 312-a and 312-b may be coupled with an output stage 360 of the voltage driver circuit 210-a, which may include the transistors 315-a and 315-b, the current sources 320-a and 320-b, and the switches 325-a and 325-b. For example, the output 312-a of the differential amplifier 305-a may be coupled with a gate of the transistor 315-a, and the output 312-b of the differential amplifier 305-b may be coupled with a gate of the transistor 315-b. In the example of voltage driver circuit 210-a, each of the transistors 315-a and 315-b may be configured in or otherwise support a common source arrangement, where a developed signal or voltage (e.g., from one of the outputs 312) may be applied to a gate of the respective transistor 315 (e.g., as an input signal) to generate a responsive signal or voltage along the channel (e.g., at the source node, at the drain node) of the respective transistor 315. In various configurations, a transistor 315 configured in a common source arrangement may provide a conversion of charge, voltage, or other signals between the gate and the channel, which may be based at least in part on a respective voltage source 335 that is coupled with the channel. For example, the transistor 315-a configured in a common source arrangement may be fed by voltage source 335-c (e.g., at a drain of the transistor 315-a), and a voltage at a source of the transistor 315-a (e.g., a voltage of the output 212-a) may be equal to a voltage at the drain of the transistor 315-a (e.g., V3) minus a voltage drop across a resistivity through the channel of the transistor 315-a, among other examples. In another example, the transistor 315-b configured in a common source arrangement may be fed by voltage source 335-a (e.g., at a source of the transistor 315-b), and a voltage at a drain of the transistor 315-b (e.g., a voltage of the output 212-a) may be equal to a voltage at the source of the transistor 315-b (e.g., V1) plus a voltage drop across a resistivity through the channel of the transistor 315-b, among other examples. In accordance with these and other examples, the range of voltage between V3 and V1 may be configured to be wider than the range of voltages to be output by the voltage driver circuit 210-a (e.g., at the output 212-a).

An electronic device that includes the circuit 300 (e.g., the voltage driver circuit 210-a) may include logic (e.g., control logic, one or more controllers, processing circuitry) operable to configure a voltage driver circuit 210 in one of a pull-up mode or a pull down mode (e.g., but not both simultaneously). For example, such logic may be operable to enable the pull-up mode using the differential amplifier 305-a based at least in part on opening the switch 325-a and closing the switch 325-b (e.g., based on logic values PUEN and PDEN having opposite states). Accordingly, in the pull-up mode, the current source 320-b may be associated with (e.g., coupled with, in accordance with a pull-up loop) the differential amplifier 305-a, such that current to the current source 320-b and to the output 212-a (e.g., an output current from the voltage driver circuit 210-a, a source current, which may be up to 2 milliamp in some implementations) may be conveyed from the voltage source 335-c via transistor 315-a. Further, such logic may be operable to enable the pull-down mode using the differential amplifier 305-b based at least in part on closing the switch 325-a and opening the switch 325-b (e.g., based on logic values PDEN and PUEN having opposite states). Accordingly, in the pull-down mode, the current source 320-a may be associated with (e.g., coupled with, in accordance with a pull-down loop) the differential amplifier 305-b, such that current from the current source 320-a and from the output 212-a (e.g., an input current into the voltage driver circuit 210-a, a sink current, which also may be up to 2 milliamp in some implementations) may be conveyed to the voltage source 335-a via transistor 315-b.

Logic for configuring operations of a voltage driver circuit 210 may be operable to enable the pull-up mode or the pull-down mode based on a voltage level (e.g., an output voltage, a regulated voltage, a target voltage for the output 212-a, a voltage VREF) determined for a voltage driver circuit 210. For example, the pull-up mode may be enabled (e.g., and the pull-down mode may be disabled) if the voltage level is within a first range (e.g., is above a threshold), and the pull-down mode may be enabled (e.g., and the pull-up mode may be disabled) is the voltage level is within a second range (e.g., is below the threshold). In some implementations, a voltage threshold for enabling the pull-up mode or the pull-down mode be a middle (e.g., average, midpoint) voltage of an overall range of regulated voltage for the voltage driver circuit 210. For example, when implemented in a memory device 100, a voltage driver circuit 210 may be configured to provide a regulated output within a configurable range between a ground voltage (e.g., 0.0V) and an array voltage (e.g., a voltage for operating a memory array 110, VARY, 1.0V). Accordingly, if a voltage level determined for the voltage driver circuit 210 is between the ground voltage and half the array voltage, logic may be configured to enable the pull-down mode and, if a voltage level determined for the voltage driver circuit 210 is between the half the array voltage and the array voltage, the logic may be configured to enable the pull-up mode. In some examples, a determination of a target voltage, enabling or disabling a pull-up or pull-down mode, or any combination thereof may be based on one or more bit values of a register, based on a fuse state of one or more fuses, or both. In some examples, such values may be used for both setting a reference voltage (e.g., from among a range of voltages, by a voltage generator 205, for activating one or more branches of a resistance ladder) and for enabling or disabling modes of a voltage driver circuit 210.

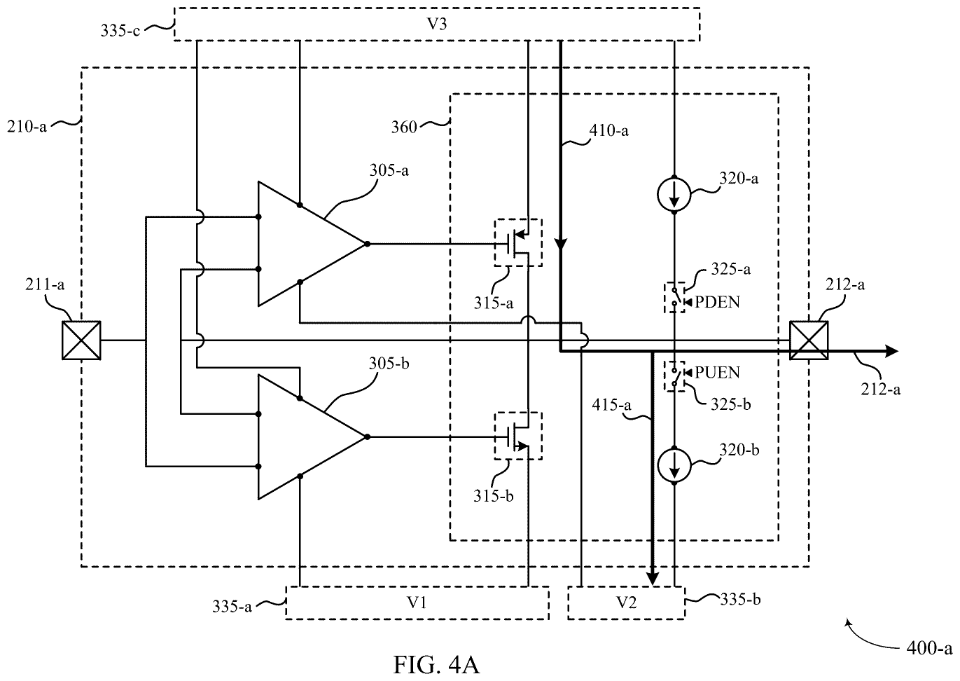

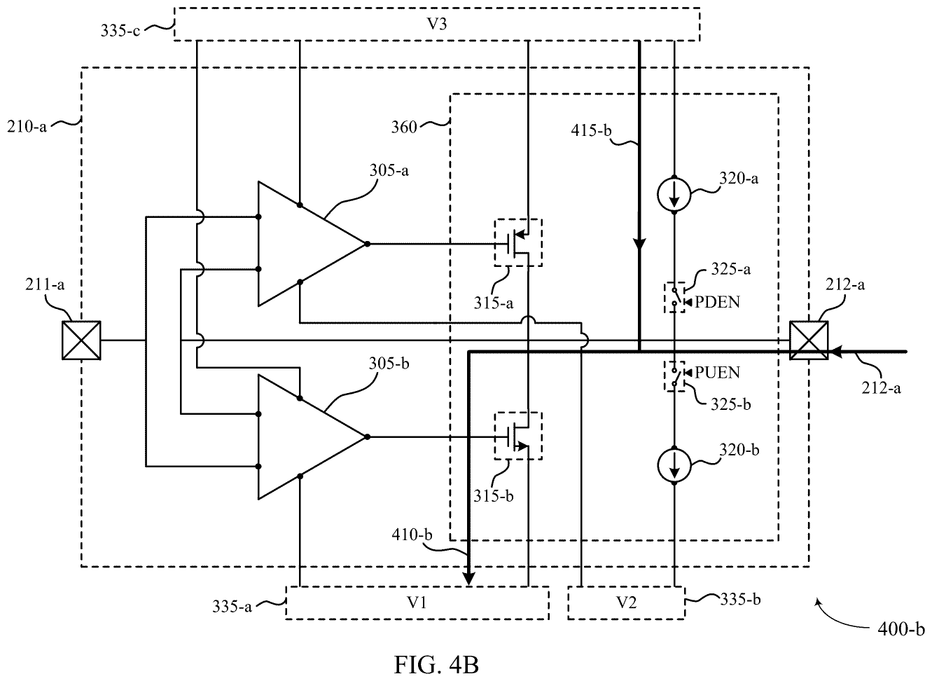

FIGS. 4A and 4B show examples of implementing voltage drivers (e.g., voltage driver circuit 210-a) with configurable pull-up and pull-down amplifiers in accordance with examples as disclosed herein.

FIG. 4A shows an implementation 400-a of the voltage driver circuit 210-a in a pull-up mode. For example, based on a first combination of values at an associated register or fuse array (e.g., which may also be used to set a voltage level applied to the input 211-a, such as a voltage above in an upper range of voltages for regulation by the voltage driver circuit 210-a, which may be above a voltage level of VARY/2), logic coupled with the voltage driver circuit 210-a may enable the pull-up mode of the voltage driver circuit 210-a by closing the switch 325-b (e.g., based on activating logical signal PUEN, to activate the differential amplifier 305-a), and opening the switch 325-a (e.g., based on deactivating logical signal PDEN, to deactivate the differential amplifier 305-b). While the pull-up mode is enabled, the activated differential amplifier 305-a may create a feedback loop from the transistor 315-a to the input 307-a, which may be based on current flow through the voltage driver circuit 210-a. For example, a current 410-a from the voltage source 335-c and through the transistor 315-a (e.g., based on a voltage at the output 312-a of the differential amplifier 305-a, based on a voltage at the gate of the transistor 315-a) may include (e.g., be divided into) a current 415-a (e.g., a current driven by the current source 320-b, from the output 212-a to the voltage source 335-b) and a current 420-a (e.g., a sourcing current, a current output from the voltage driver circuit 210-a). By disabling the differential amplifier 305-b during the pull-up mode, the voltage driver circuit 210-a may be configured to support a sourcing current with reduced latency, reduced offsets, and increased reliability during voltage regulation operations.

FIG. 4B shows an implementation 400-b of the voltage driver circuit 210-a in a pull-down mode. For example, based on a second combination of values at an associated register or fuse array (e.g., which may also be used to set a voltage level applied to the input 211-a, such as a voltage above in a lower range of voltages for regulation by the voltage driver circuit 210-a, which may be below a voltage level of VARY/2), logic coupled with the voltage driver circuit 210-a may enable the pull-down mode of the voltage driver circuit 210-a by closing the switch 325-a (e.g., based on activating logical signal PDEN, to activate the differential amplifier 305-b), and opening the switch 325-b (e.g., based on deactivating logical signal PUEN, to deactivate the differential amplifier 305-a). While the pull-down mode is enabled, the activated differential amplifier 305-b may create a feedback loop from the transistor 315-b to the input 307-b, which may be based on current flow through the voltage driver circuit 210-a. For example, a current 410-b to the voltage source 335-a and through the transistor 315-b (e.g., based on a voltage at the output 312-b of the differential amplifier 305-b, based on a voltage at the gate of the transistor 315-b) may include (e.g., be a combination of) a current 415-b (e.g., a current driven by the current source 320-a, from the voltage source 335-c to the output 212-a) and a current 420-b (e.g., a sinking current, a current input to the voltage driver circuit 210-a). By disabling the differential amplifier 305-a during the pull-down mode, the voltage driver circuit 210-a may be configured to support a sinking current with reduced latency, reduced offsets, and increased reliability during voltage regulation operations.

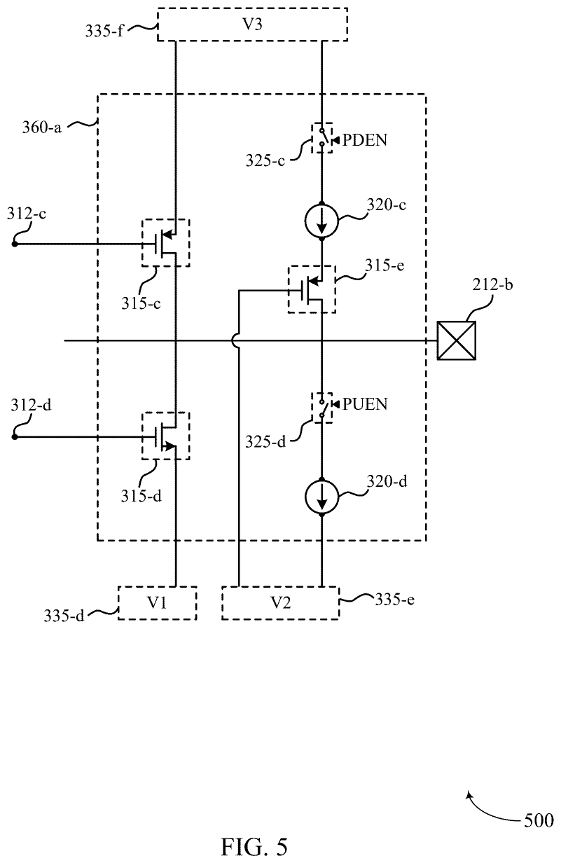

FIG. 5 shows an example of a circuit 500 that supports voltage drivers with configurable pull-up and pull-down amplifiers in accordance with examples as disclosed herein. The circuit 500 includes an example of an output stage 360-a, between outputs 312-c and 312-d (e.g., of differential amplifiers 305, not shown) and an output 212-b, that may be implemented in a voltage driver circuit 210. The output stage 360-a may include aspects that are similar to the output stage 360 of the voltage driver circuit 210-a, but may also include cascode protection to limit voltages across circuit elements (e.g., transistors 315) of the output stage 360-a.

The circuit 500 includes voltage sources 335 where, similar to the circuit 300, the voltage source 335-d may be associated with the voltage V1 (e.g., a negative supply voltage, VBB, −0.5V), the voltage source 335-e may be associated with the voltage V2 (e.g., VSS, 0.0V, a ground voltage, a ground node), and the voltage source 335-f may be associated with the voltage V3 (e.g., a positive supply voltage, VPERI, 1.1V). The circuit 500 (e.g., the output stage 360-a) also includes switches 325, where a switch 325-c may be operable based on a logical signal PDEN (e.g., a pull-down enable signal), and a switch 325-d may be operable based on a logical signal PUEN (e.g., a pull-up enable signal). The circuit 300 (e.g., the output stage 360-a) also includes current sources 320, where a current source 320-c may be operable to drive a current (e.g., via switch 325-c, while closed) to the output 212-b, and a current source 320-b may be operable to drive a current (e.g., via switch 325-b, while closed) from the output 212-a. The switch 325-c may be coupled between voltage source 335-f and the current source 320-c and the output 212-b, and the switch 325-d may be coupled between the output 212-b and the current source 320-d. The circuit 500 (e.g., the output stage 360-a) also includes transistors 315, where a transistor 315-c may have a channel operable to couple between the voltage source 335-f and the output 212-b, and a transistor 315-d may have a channel operable to couple between the output 212-b and the voltage source 335-d. In some implementations, the transistor 315-c may be a p-type transistor, and the transistor 315-d may be an n-type transistor.

The circuit 500 (e.g., the output stage 360-a) may also include a transistor 315-c (e.g., along a pull-down portion of the output stage 360-a), which may support a cascode protection that prevents components of the output stage 360-a experiencing a full voltage swing between V1 and V3 (e.g., 1.6V). For example, the transistor 315-e configured in a cascode arrangement may be referred to as a voltage regulator or a bias component, relating to how the transistor 315-e may regulate a flow of charge in response to a voltage across the transistor 315-c. In such an implementation, a gate of the transistor 315-e may be biased with the voltage V2 (e.g., 0.0V, a ground voltage, in accordance with a common source configuration), such that a voltage at a drain side of the transistor 315-c (e.g., and the current source 320-c and switch 325-c) may be limited to a value of V2 plus the threshold voltage of the transistor 315-c. In some examples, components on the drain side of the transistor 315-c may thus experience a voltage swing closer to V3−V2, rather than a voltage of V3−V1 (e.g., a relatively lower voltage swing). Accordingly, with such protection (e.g., as a reduction in voltage differential), more circuit elements (e.g., transistors 315) of the output stage 360-a may be able to implement thinner isolation (e.g., thinner gate dielectric), which may support relatively higher robustness, higher reliability, smaller devices, or denser circuitry, among other benefits. Such protection may not be implemented along a pull-up portion of the output stage 360-a (e.g., between the output 212-b and the switch 326-d and/or current source 320-d) because a voltage swing experienced by such components may already be relatively lower (e.g., closer to the voltage differential of V3−V2).

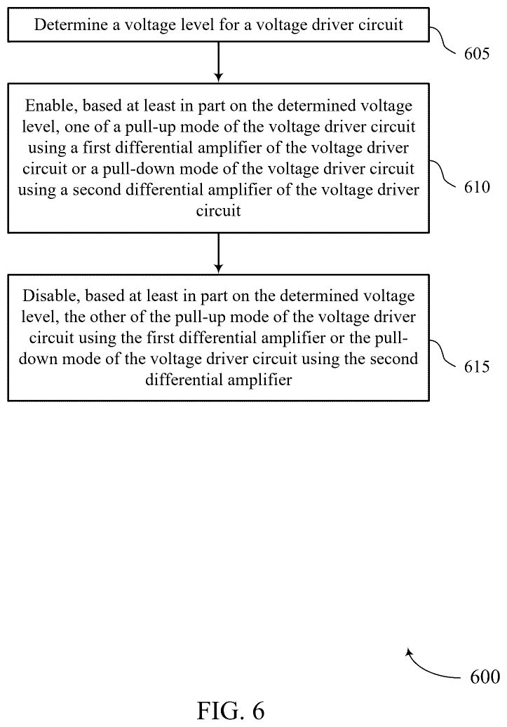

FIG. 6 shows a flowchart illustrating a method 600 that supports voltage drivers with configurable pull-up and pull-down amplifiers in accordance with examples as disclosed herein. The operations of method 800 may be implemented by an electronic device or its components as described herein. For example, the operations of method 600 may be performed by an electronic device as described with reference to FIGS. 1 through 5. In some examples, an electronic device may execute a set of instructions to control the functional elements of the device to perform the described functions. Additionally, or alternatively, the electronic device may perform aspects of the described functions using special-purpose hardware.

At 605, the method may include determining a voltage level for a voltage driver circuit (e.g., determining VREF, determining an output voltage for a reference generator 205, determining target voltages for one or more outputs 212).

At 610, the method may include enabling, based at least in part on the determined voltage level, one of a pull-up mode of the voltage driver circuit using a first differential amplifier of the voltage driver circuit or a pull-down mode of the voltage driver circuit using a second differential amplifier of the voltage driver circuit.

At 615, the method may include disabling, based at least in part on the determined voltage level, the other of the pull-up mode of the voltage driver circuit using the first differential amplifier or the pull-down mode of the voltage driver circuit using the second differential amplifier.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for determining a voltage level for a voltage driver circuit; enabling, based at least in part on the determined voltage level, one of a pull-up mode of the voltage driver circuit using a first differential amplifier of the voltage driver circuit or a pull-down mode of the voltage driver circuit using a second differential amplifier of the voltage driver circuit; and disabling, based at least in part on the determined voltage level, the other of the pull-up mode of the voltage driver circuit using the first differential amplifier or the pull-down mode of the voltage driver circuit using the second differential amplifier.

Aspect 2: The method, apparatus, or non-transitory computer-readable medium of aspect 1, where the first differential amplifier has a first differential input coupled with an input node of the voltage driver circuit, a second differential input coupled with an output node of the voltage driver circuit, a first supply input operable to couple with a first voltage source, and a second supply input operable to couple with a second voltage source and the second differential amplifier has a third differential input coupled with the input node of the voltage driver circuit, a fourth differential input coupled with the output node of the voltage driver circuit, a third supply input operable to couple with the first voltage source, and a fourth supply input coupled with a third voltage source associated with a lower voltage than the second voltage source.

Aspect 3: The method, apparatus, or non-transitory computer-readable medium of any of aspects 1 through 2, where the first differential amplifier has an output coupled with a gate of a first transistor, the first transistor having a channel between the first voltage source and the output node of the voltage driver circuit and the second differential amplifier has an output coupled with a gate of a second transistor, the second transistor having a channel between the output node of the voltage driver circuit and the third voltage source.

Aspect 4: The method, apparatus, or non-transitory computer-readable medium of any of aspects 1 through 3, where determining the voltage level for the driver circuit is based at least in part on a value of a register, one or more one-time programmable storage elements, or a combination thereof.

Aspect 5: The method, apparatus, or non-transitory computer-readable medium of any of aspects 1 through 4, where the enabling includes enabling the pull-up mode using the first differential amplifier if the voltage level is above a voltage threshold or enabling the pull-down mode using the second differential amplifier if the voltage level is below the voltage threshold and the disabling includes disabling the pull-down mode using the second differential amplifier if the voltage level is above the voltage threshold or disabling the pull-up mode using the first differential amplifier if the voltage level is below the voltage threshold.

Aspect 6: The method, apparatus, or non-transitory computer-readable medium of any of aspects 1 through 5, where the voltage driver circuitry includes a first current source operable to drive a first current via a first switch and to the output node and a second current source operable to drive a second current via a second switch and from the output node, and: enabling the pull-up mode using the first differential amplifier includes closing the second switch; enabling the pull-down mode using the second differential amplifier includes closing the first switch; disabling the pull-up mode using the first differential amplifier includes opening the second switch; and disabling the pull-down mode using the second differential amplifier includes opening the first switch.

It should be noted that the methods described herein are possible implementations, and that the operations and the steps may be rearranged or otherwise modified and that other implementations are possible. Furthermore, portions from two or more of the methods may be combined.

An apparatus is described. The following provides an overview of aspects of the apparatus as described herein:

Aspect 7: An electronic device, including: a voltage driver circuit having an input node and an output node, the voltage driver circuit including: a first transistor having a first channel operable to couple between a first voltage source and the output node, and having a first gate operable to modulate a conductivity of the first channel; a second transistor having a second channel operable to couple between the output node and a second voltage source, and having a second gate operable to modulate a conductivity of the second channel; a first current source operable to drive a first current via a first switch and to the output node; a second current source operable to drive a second current via a second switch and from the output node; a first differential amplifier having a first differential input coupled with the input node, having a second differential input coupled with the output node, and having a first output coupled with the first gate; and a second differential amplifier having a third differential input coupled with the input node, having a fourth differential input coupled with the output node, and having a second output coupled with the second gate.

Aspect 8: The electronic device of aspect 7, further including: logic operable to cause the electronic device to: enable a pull-up mode of the voltage driver circuit using the first differential amplifier based at least in part on opening the first switch and closing the second switch; and enable a pull-down mode of the voltage driver circuit using the second differential amplifier based at least in part on closing the first switch and opening the second switch.

Aspect 9: The electronic device of aspect 8, where: while the pull-up mode is enabled, the second current source is configured to drive the second current via the first transistor; and while the pull-down mode is enabled, the first current source is configured to drive the first current via the second transistor.

Aspect 10: The electronic device of any of aspects 8 through 9, where the logic is operable to cause the electronic device to: enable the pull-up mode or the pull-down mode based at least in part on one or more bit values of a register of the electronic device, on one or more fuse states of a fuse array at the electronic device, or a combination thereof.

Aspect 11: The electronic device of any of aspects 7 through 10, where: the first differential amplifier has a first supply input operable to couple with the first voltage source and a second supply input operable to couple with a third voltage source; and the second differential amplifier has a third supply input operable to couple with the first voltage source and a fourth supply input operable to couple with the second voltage source.

Aspect 12: The electronic device of aspect 11, where: the first current source has an input operable to couple with the first voltage source and an output operable to couple with the output node; and the second current source has an input operable to couple with the output node and an output operable to couple with the third voltage source.

Aspect 13: The electronic device of aspect 12, where: the first switch is coupled between the first voltage source and the input of the first current source; and the second switch is coupled between the output node and the input of the second current source.

Aspect 14: The electronic device of any of aspects 11 through 13, where: the first voltage source is associated with a positive voltage; the second voltage source is associated with a negative voltage; and the third voltage source is associated with a voltage between the positive voltage and the negative voltage.

Aspect 15: The electronic device of aspect 14, where the voltage driver circuit further includes: a third transistor having a third channel, operable to couple between the first current source and the output node, and a third gate operable to modulate a conductivity of the third channel and being coupled with the third voltage source.

Aspect 16: The electronic device of any of aspects 14 through 15, where the voltage between the positive voltage and the negative voltage is a ground voltage.

Aspect 17: The electronic device of any of aspects 7 through 16, where: the first transistor is a p-type transistor; and the second transistor is an n-type transistor.

Aspect 18: The electronic device of any of aspects 7 through 17, where: the first differential amplifier is associated with a first operational range of output voltages at the output node; and the second differential amplifier is associated with a second operational range of output voltages at the output node that is lower than the first operational range of output voltages.

Aspect 19: The electronic device of any of aspects 7 through 18, where the voltage driver circuit is associated with a unity gain between the input node and the output node.

Aspect 20: The electronic device of any of aspects 7 through 19, further including: a plurality of banks of memory cells, where respective circuitry of each bank of the plurality of banks is coupled with the output node of a respective instance of the voltage driver circuit.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals can be communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected with other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An electronic device, comprising:
a voltage driver circuit having an input node and an output node, the voltage driver circuit comprising:
a first transistor having a first channel operable to couple between a first voltage source and the output node, and having a first gate operable to modulate a conductivity of the first channel;
a second transistor having a second channel operable to couple between the output node and a second voltage source, and having a second gate operable to modulate a conductivity of the second channel;
a first current source operable to drive a first current via a first switch and to the output node;
a second current source operable to drive a second current via a second switch and from the output node;
a first differential amplifier having a first differential input coupled with the input node, having a second differential input coupled with the output node, and having a first output coupled with the first gate; and
a second differential amplifier having a third differential input coupled with the input node, having a fourth differential input coupled with the output node, and having a second output coupled with the second gate.

2. The electronic device of claim 1, further comprising:
logic operable to cause the electronic device to:
enable a pull-up mode of the voltage driver circuit using the first differential amplifier based at least in part on opening the first switch and closing the second switch; and
enable a pull-down mode of the voltage driver circuit using the second differential amplifier based at least in part on closing the first switch and opening the second switch.

3. The electronic device of claim 2, wherein:
while the pull-up mode is enabled, the second current source is configured to drive the second current via the first transistor; and
while the pull-down mode is enabled, the first current source is configured to drive the first current via the second transistor.

4. The electronic device of claim 2, wherein the logic is operable to cause the electronic device to:
enable the pull-up mode or the pull-down mode based at least in part on one or more bit values of a register of the electronic device, on one or more fuse states of a fuse array at the electronic device, or a combination thereof.

5. The electronic device of claim 1, wherein:
the first differential amplifier has a first supply input operable to couple with the first voltage source and a second supply input operable to couple with a third voltage source; and
the second differential amplifier has a third supply input operable to couple with the first voltage source and a fourth supply input operable to couple with the second voltage source.

6. The electronic device of claim 5, wherein:
the first current source has an input operable to couple with the first voltage source and an output operable to couple with the output node; and
the second current source has an input operable to couple with the output node and an output operable to couple with the third voltage source.

7. The electronic device of claim 6, wherein:
the first switch is coupled between the first voltage source and the input of the first current source; and
the second switch is coupled between the output node and the input of the second current source.

8. The electronic device of claim 5, wherein:
the first voltage source is associated with a positive voltage;
the second voltage source is associated with a negative voltage; and
the third voltage source is associated with a voltage between the positive voltage and the negative voltage.

9. The electronic device of claim 8, wherein the voltage driver circuit further comprises:
a third transistor having a third channel, operable to couple between the first current source and the output node, and a third gate operable to modulate a conductivity of the third channel and being coupled with the third voltage source.

10. The electronic device of claim 8, wherein the voltage between the positive voltage and the negative voltage is a ground voltage.

11. The electronic device of claim 1, wherein:
the first transistor is a p-type transistor; and
the second transistor is an n-type transistor.

12. The electronic device of claim 1, wherein:
the first differential amplifier is associated with a first operational range of output voltages at the output node; and
the second differential amplifier is associated with a second operational range of output voltages at the output node that is lower than the first operational range of output voltages.

13. The electronic device of claim 1, wherein the voltage driver circuit is associated with a unity gain between the input node and the output node.

14. The electronic device of claim 1, further comprising:
a plurality of banks of memory cells, wherein respective circuitry of each bank of the plurality of banks is coupled with the output node of a respective instance of the voltage driver circuit.

15. A method, comprising:
determining a voltage level for a voltage driver circuit;
enabling, based at least in part on the determined voltage level, one of a pull-up mode of the voltage driver circuit using a first differential amplifier of the voltage driver circuit or a pull-down mode of the voltage driver circuit using a second differential amplifier of the voltage driver circuit; and
disabling, based at least in part on the determined voltage level, the other of the pull-up mode of the voltage driver circuit using the first differential amplifier or the pull-down mode of the voltage driver circuit using the second differential amplifier.

16. The method of claim 15, wherein:
the first differential amplifier has a first differential input coupled with an input node of the voltage driver circuit, a second differential input coupled with an output node of the voltage driver circuit, a first supply input operable to couple with a first voltage source, and a second supply input operable to couple with a second voltage source; and
the second differential amplifier has a third differential input coupled with the input node of the voltage driver circuit, a fourth differential input coupled with the output node of the voltage driver circuit, a third supply input operable to couple with the first voltage source, and a fourth supply input coupled with a third voltage source associated with a lower voltage than the second voltage source.

17. The method of claim 16, wherein:
the first differential amplifier has an output coupled with a gate of a first transistor, the first transistor having a channel between the first voltage source and the output node of the voltage driver circuit; and
the second differential amplifier has an output coupled with a gate of a second transistor, the second transistor having a channel between the output node of the voltage driver circuit and the third voltage source.

18. The method of claim 15, wherein determining the voltage level for the voltage driver circuit is based at least in part on a value of a register, one or more one-time programmable storage elements, or a combination thereof.

19. The method of claim 15, wherein:
the enabling comprises enabling the pull-up mode using the first differential amplifier if the voltage level is above a voltage threshold or enabling the pull-down mode using the second differential amplifier if the voltage level is below the voltage threshold; and
the disabling comprises disabling the pull-down mode using the second differential amplifier if the voltage level is above the voltage threshold or disabling the pull-up mode using the first differential amplifier if the voltage level is below the voltage threshold.

20. The method of claim 15, wherein the voltage driver circuit comprises:
a first current source operable to drive a first current via a first switch and to an output node of the voltage driver circuit; and
a second current source operable to drive a second current via a second switch and from the output node, and wherein:
enabling the pull-up mode using the first differential amplifier comprises closing the second switch;
enabling the pull-down mode using the second differential amplifier comprises closing the first switch;
disabling the pull-up mode using the first differential amplifier comprises opening the second switch; and
disabling the pull-down mode using the second differential amplifier comprises opening the first switch.
